(19) United States
(12) Patent Application Publication
(10) Pub. No.: US 2026/0112045 A1
(43) Pub. Date: Apr. 23, 2026

(54) DEFECT MAP BASED D2D ALIGNMENT OF IMAGES FOR MACHINE LEARNING TRAINING DATA PREPARATION

(71) Applicant: ASML NETHERLANDS B.V., Veldhoven (NL)

(72) Inventors: Daekwon KANG, Pleasanton, CA (US); Chen ZHANG, San Jose, CA (US); Jun TAO, San Jose, CA (US); Jiao LIANG, San Jose, CA (US); Qian ZHAO, San Jose, CA (US); Mu FENG, San Jose, CA (US)

(73) Assignee: ASML NETHERLANDS B.V., Veldhoven (NL)

(21) Appl. No.: 19/115,986

(22) PCT Filed: Sep. 21, 2023
(86) PCT No.: PCT/EP2023/076163

§ 371 Date: Mar. 27, 2025

Related U.S. Application Data
(60) Provisional application No. 63/418,316, filed on Oct. 21, 2022.

(51) Int. Cl. G06T 7/33; G03F 7/00; G06T 7/00

(52) U.S. Cl. CPC G06T 7/337; G03F 7/706841; G06T 7/001; G06T 2207/20016; G06T 2207/20081; G06T 2207/20084; G06T 2207/20132; G06T 2207/30148; G06T 2207/30204

(57) ABSTRACT

A method for die-to-die (D2D) image alignment using a defect map associated with an image. The method includes accessing a set of images of a substrate, which correspond to different image capture conditions. The locations of various defects on the set of images are obtained and a defect map indicating relative locations of at least some of the defects is generated. The set of images are aligned with each other using the defect map to generate an aligned set of images.

### CROSS-REFERENCE TO RELATED APPLICATIONS

This application claims priority of U.S. application 63/418,316 which was filed on Oct. 21, 2022 and which is incorporated herein in its entirety by reference.

### TECHNICAL FIELD

The embodiments provided herein relate to semiconductor manufacturing, and more particularly to semiconductor metrology and inspection.

### BACKGROUND

A lithographic apparatus is a machine that applies a desired pattern onto a target portion of a substrate. The lithographic apparatus can be used, for example, in the manufacture of integrated circuits (ICs). For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects.

Metrology processes are used at various steps during a patterning process to monitor and/or control the process. For example, metrology processes are used to measure one or more characteristics of a substrate, such as a relative location (e.g., registration, overlay, alignment, etc.) or dimension (e.g., line width, critical dimension (CD), thickness, etc.) of features formed on the substrate during the patterning process or stochastic variation, such that, for example, the performance of the patterning process can be determined from the one or more characteristics. If the one or more characteristics are unacceptable (e.g., out of a predetermined range for the characteristic(s)), one or more variables of the patterning process may be designed or altered, e.g., based on the measurements of the one or more characteristics, such that substrates manufactured by the patterning process have an acceptable characteristic(s).

Wafer inspection is a process to find a defect on a wafer. One of the ways the inspection process determines a defect includes a wafer inspection tool taking an image of a die, then, taking an image of another die and comparing them. If there's a change, that's generally a defect. The inspection tool may find defects and also detect a false defect what is commonly called as a “nuisance.” In more advanced nodes, the nuisances and defects appear to be bunched together on the map and it's difficult to distinguish the differences between the two. Detection of nuisances from the defects may typically require high quality or high-resolution images to find a defect of interest.

However, a significant amount of time is consumed in capturing a high-resolution image.

Image capture times for low-quality or low-resolution images are much faster than that of the high-quality images but may not help in identifying the defects from nuisances. Machine learning (ML) models provide the solutions to improve the image quality from low to high quality with an acceptable defect capture rate (defect to nuisance ratio). ML models may require pairs of low-resolution and high-resolution image as training data to convert a low-resolution image to high resolution image and these training pairs may have to a well-aligned image pair. Aligning low-resolution and high-resolution images may be performed when there are distinctive patterns in the images. Conventional techniques may not align two images without a distinctive pattern. These and other drawbacks exist.

### BRIEF SUMMARY

In some embodiments, there is provided a non-transitory computer readable medium having instructions that, when executed by a computer, cause the computer to execute a method for image alignment. The method includes accessing a set of images of a substrate, wherein the set of images correspond to different image capture conditions; obtaining locations of multiple defects on the set of images; determining a defect map indicating relative locations of at least some of the defects; and aligning the set of images with each other using the defect map to generate an aligned set of images.

In some embodiments, there is provided a non-transitory computer readable medium having instructions that, when executed by a computer, cause the computer to execute a method for training a machine learning model to generate an image indicative of defects on a substrate. The method includes: obtaining a set of images of the substrate, wherein the set of images correspond to different image capture conditions; generating a defect map associated with set of images; aligning the set of images with each other based on the defect map to generate an aligned set of images; and training, based on multiple aligned sets of images, a neural network to generate a predicted image of the substrate, wherein the predicted image includes a group of defects on the substrate.

In some embodiments, there is provided a method for image alignment. The method includes accessing a set of images of a substrate, wherein the set of images correspond to different image capture conditions; obtaining locations of multiple defects on the set of images; determining a defect map indicating relative locations of at least some of the defects; and aligning the set of images with each other using the defect map to generate an aligned set of images.

In some embodiments, there is provided an apparatus for image alignment. The apparatus includes a memory storing a set of instructions and a processor configured to execute the set of instructions to cause the apparatus to perform a method of accessing a set of images of a substrate, wherein the set of images correspond to different image capture conditions; obtaining locations of multiple defects on the set of images; determining a defect map indicating relative locations of at least some of the defects; and aligning the set of images with each other using the defect map to generate an aligned set of images.

### BRIEF DESCRIPTION OF THE DRAWINGS

Embodiments will now be described, by way of example only, with reference to the accompanying drawings in which:

FIG. 1 is a schematic diagram illustrating an exemplary electron beam inspection (EBI) system, according to an embodiment.

FIG. 2 is a schematic diagram of an exemplary electron beam tool, according to an embodiment.

FIG. 3 depicts a schematic representation of holistic lithography, representing a cooperation between three technologies to optimize semiconductor manufacturing, according to an embodiment.

FIG. 4 is a block diagram of an exemplary system for aligning images of a substrate using a defect map associated with the images, consistent with various embodiments.

FIG. 5 is a flow diagram of an exemplary method for aligning images of a substrate using a defect map associated with the images, consistent with various embodiments.

FIG. 6 is a block diagram of a system for training an image generator to generate a high-resolution image of a defect on a substrate based on a low-resolution image of the defect, consistent with various embodiments.

FIG. 7 is a block diagram of a system for predicting a high-resolution image of a defect on a substrate based on a low-resolution image of the defect, consistent with various embodiments.

FIG. 8 is a block diagram of an example computer system, according to an embodiment.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

A lithographic apparatus is a machine that applies a desired pattern onto a target portion of a substrate. This process of transferring the desired pattern to the substrate is called a patterning process. The patterning process can include a patterning step to transfer a pattern from a patterning device (such as a mask) to the substrate. Various variations (e.g., variations in the patterning process or the lithographic apparatus) can potentially limit lithography implementation for semiconductor high volume manufacturing (HVM). High resolution images (e.g., images with resolution above a specified threshold) of a substrate, such as images obtained using a scanning electron microscope (SEM), may be inspected for determining any defects in the patterning process. Conventional techniques employ various computational methods for obtaining the high resolution (HR) images of defects on the substrate. For example, machine learning (ML) models are employed to generate HR images showing a defect on the substrate based on the low resolution (LR) images (e.g., images with resolution below the specified threshold) bearing the defect (e.g., obtained using the SEM). The ML models are trained using LR and HR image pairs of the defect region to predict a HR image.

However, the conventional techniques have a problem. For example, the LR and HR image pair of the defect region in the training data have to be of the same location on the substrate (e.g., same die). In such a case, the number of image pairs of the defect region available will be limited and insufficient for use in training the ML model. In some embodiments, some cases, images for different locations on the substrate (e.g., images of different dies on the substrate) may be used by performing a die-to-die (D2D) alignment of the LR and HR images. However, the conventional D2D image alignment may require presence of distinctive patterns in the images, and if there are none or limited number of distinctive patterns or if the image quality of LR images is insufficient, the D2D alignment may fail. These and other drawbacks exist.

Disclosed are embodiments for performing alignment of images of different resolutions that correspond to the same pattern on a substrate. For example, the embodiments may include performing D2D image alignment of images of different locations (e.g., different dies) on a substrate. The embodiments may perform the alignment using a defect map, which is an image indicating locations of defects on the substrate. A first defect map of a first image obtained using a first image capture condition (e.g., HR image of the defect region on the substrate) and a second defect map of a second image obtained using a second image capture condition (e.g., LR image of a defect region on the substrate) are generated based on defect data. The defect maps are analyzed to generate processed defect maps (e.g., which include defects that are common between both the defect maps). The second processed defect map is aligned with the first processed defect map (e.g., based on the coordinates of the common defects) and an offset value, which is indicative of a direction and magnitude by which the second process defect map had to be shifted to align with the first processed defect map, is obtained. The LR image is then aligned with the HR image based on the offset value. The aligned images may then be used as training data for training a ML model to predict a HR image of a substrate based on LR image of the substrate. By using a defect map to align the images of different locations of a substrate, the need for having distinctive patterns in the images to be aligned is minimized or eliminated, and the problem of having insufficient data in cases where the ML models are to be trained using images of the same location on the substrate is also overcome.

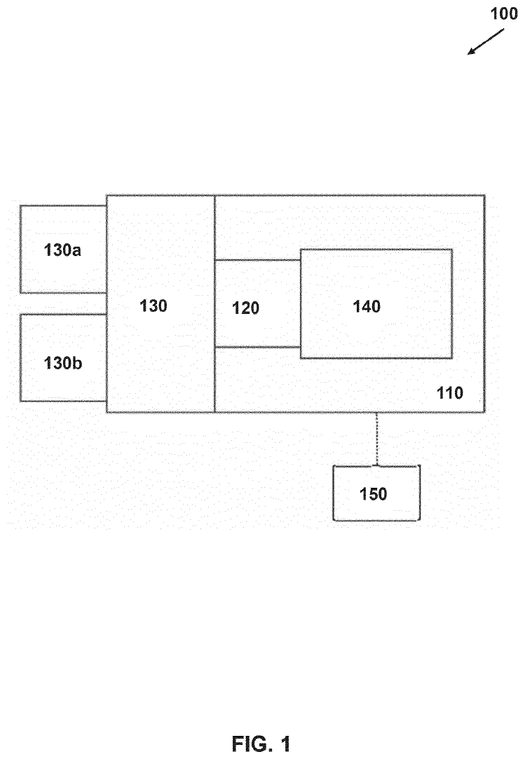

Reference is now made to FIG. 1, which illustrates an exemplary electron beam inspection (EBI) system 100 consistent with embodiments of the present disclosure. As shown in FIG. 1, EBI system 100 includes a main chamber 110, a load-lock chamber 120, an electron beam tool 140, and an equipment front end module (EFEM) 130. Electron beam tool 140 is located within main chamber 110. The exemplary EBI system 100 may be a single or multi-beam system. While the description and drawings are directed to an electron beam, it is appreciated that the embodiments are not used to limit the present disclosure to specific charged particles.

EFEM 130 includes a first loading port 130a and a second loading port 130b. EFEM 130 may include additional loading port(s). First loading port 130a and second loading port 130b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 130 transport the wafers to load-lock chamber 120.

Load-lock chamber 120 is connected to a load/lock vacuum pump system (not shown), which removes gas molecules in load-lock chamber 120 to reach a first pressure below the atmospheric pressure. After reaching the first pressure, one or more robot arms (not shown) transport the wafer from load-lock chamber 120 to main chamber 110. Main chamber 110 is connected to a main chamber vacuum pump system (not shown), which removes gas molecules in main chamber 110 to reach a second pressure below the first pressure. After reaching the second pressure, the wafer is subject to inspection by electron beam tool 140. In some embodiments, electron beam tool 140 may comprise a single-beam inspection tool.

Controller 150 may be electronically connected to electron beam tool 140 and may be electronically connected to other components as well. Controller 150 may be a computer configured to execute various controls of EBI system 100. Controller 150 may also include processing circuitry configured to execute various signal and image processing functions. While controller 150 is shown in FIG. 1 as being outside of the structure that includes main chamber 110, load-lock chamber 120, and EFEM 130, it is appreciated that controller 150 can be part of the structure.

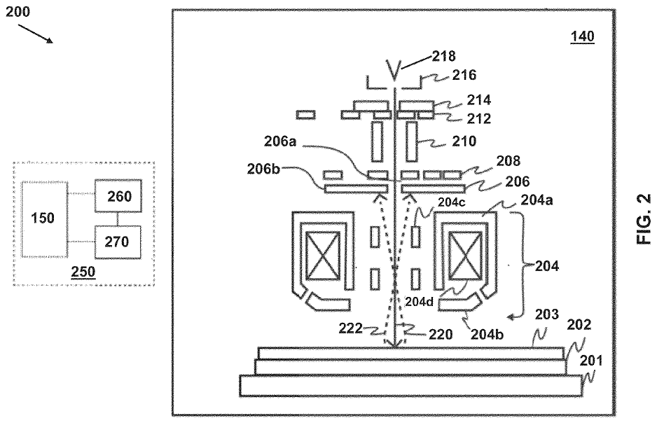

FIG. 2 illustrates schematic diagram of an exemplary imaging system 200 according to embodiments of the present disclosure. Electron beam tool 140 of FIG. 2 may be configured for use in EBI system 100. Electron beam tool 140 may be a single beam apparatus or a multi-beam apparatus. As shown in FIG. 2, electron beam tool 140 includes a motorized sample stage 201, and a wafer holder 202 supported by motorized sample stage 201 to hold a wafer 203 to be inspected.

Electron beam tool 140 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 140 may additionally include an Energy Dispersive X-ray Spectrometer (EDS) detector (not shown) to characterize the materials on wafer 203.

A primary electron beam 220 is emitted from cathode 218 by applying a voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may be configured to generate multiple primary electron beams 220, and electron beam tool 140 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, etc.) that represents an intensity of the beam spot, and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on sample stage 201, and comprises an electron beam tool 140, as discussed above. Imaging system 200 may also comprise an image processing system 250 that includes an image acquirer 260, storage 270, and controller 150. Image acquirer 260 may comprise one or more processors. For example, image acquirer 260 may comprise a computer, server, mainframe host, terminals, personal computer, any kind of mobile computing devices, and the like, or a combination thereof. Image acquirer 260 may connect with a detector 206 of electron beam tool 140 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may be configured to perform adjustments of brightness and contrast, etc. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 150. In some embodiments, image acquirer 260, storage 270, and controller 150 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image comprising a plurality of imaging areas. The single image may be stored in storage 270. The single image may be an original image that may be divided into a plurality of regions. Each of the regions may comprise one imaging area containing a feature of wafer 203.

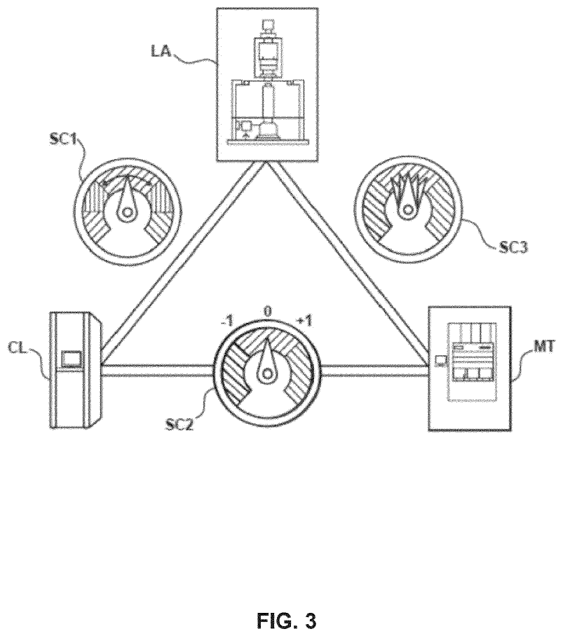

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)-typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 2 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 2 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

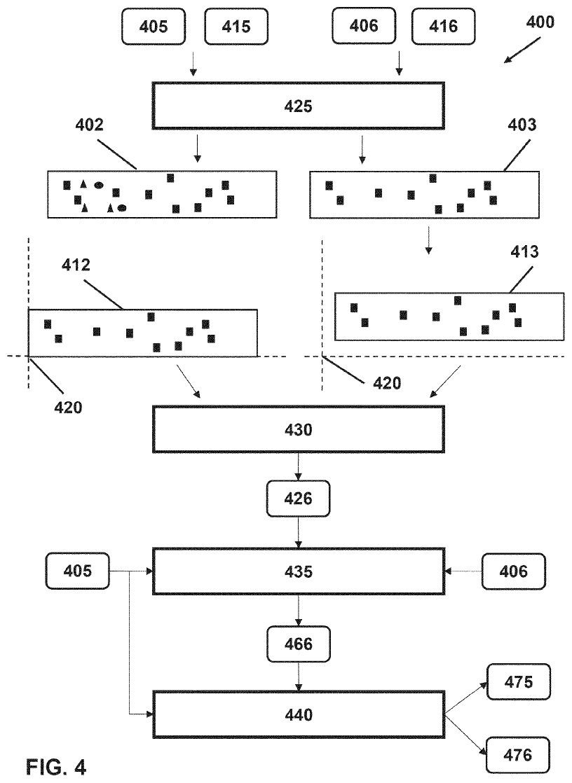

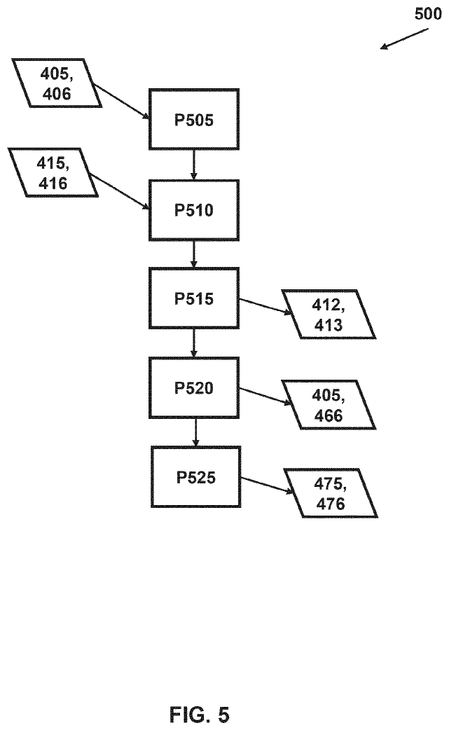

The following paragraphs describe a system and a method to perform die-to-die (D2D) alignment of images of a substrate using a defect map associated with the images. FIG. 4 is a block diagram of an exemplary system 400 for aligning images of a substrate using a defect map associated with the images, consistent with various embodiments. FIG. 5 is a flow diagram of an exemplary method 500 for aligning images of a substrate using a defect map associated with the images, consistent with various embodiments.

At process P505, a defect map generation component 425 obtains a set of images of a substrate that correspond to different image capture conditions. In some embodiments, the defect map generation component 425 may obtain a first image 405 corresponding to a first image capture condition and a second image 406 corresponding to a second image capture condition. For example, the first image capture condition may be indicative of a high resolution (HR) image and the second image capture condition may be indicative of a low resolution (LR) image, and accordingly, the first image 405 may be an HR image and the second image 406 may be a LR image of a defect region on a patterned substrate. The portion of the substrate captured in the images may or not may have distinctive patterns. In some embodiments, the images 405 and 406 do not have distinctive patterns. Further, the images 405 and 406 may correspond to the defect region in the same location (e.g., same die) or different locations (e.g., different dies) on the substrate. For example, the first image 405 may be a HR image of a defect region in a first die of a substrate and the second image 406 may be a LR image of the defect region in a second die of the substrate. Note that the following paragraphs refer to the first image 405 as “HR image” 405 and the second image 406 as “LR image” 406 but the first and second images 405 and 406 are not restricted to being HR and LR images, respectively, and could be images corresponding any other image capture conditions. In some embodiments, the LR image 406 may be missing some of the defects indicated in the HR image 405, or may include some false defects, e.g., defects that are not indicated in the HR image 405. Further, not all defects indicated in the HR image 405 may be actual defects. For example, some of the defects indicated in the HR image 405 may be image noise. The defects on the HR image may be classified into one or more categories in a variety of ways. For example, a user may classify the defects as actual defects or noise/nuisance.

In some embodiments, the images 405 and 406 may be generated using an imaging apparatus such as a SEM, and may be stored in a storage system (not illustrated), such as a database. The defect map generation component 425 may access the images 405 and 406 from the storage system.

At process P510, the defect map generation component 425 may obtain locations of defects on the images 405 and 406. In some embodiments, the defect map generation component 425 obtains the locations of defects using defect data associated with the images 405 and 406. The defect data may be indicative of the co-ordinates of the defects in an image of the substrate. For example, first defect data 415 may be indicative of the coordinates of the defects represented in the HR image 405 and second defect data 416 may be indicative of the coordinates of the defects represented in the LR image 406. The defect data may be generated in various ways. For example, the defect data may be generated using a metrology or inspection tool, such as the one in FIGS. 1 and 2. The defect data may be stored in any of various formats in the storage system. For example, the defect data may be stored as a file in the storage system and may be associated with a corresponding image of the substrate. The defect map generation component 425 may access the images 405 and 406 and their corresponding defect data from the storage system.

At process P515, the defect map generation component 425 may determine a defect map indicating relative locations of the defects in the image. In some embodiments, a defect map is an image including markers at various locations representing the defects on the images of the substrate. For example, a first defect map 402 indicates the relative locations of the defects in the HR image 405, and a second defect map 403 indicates the relative locations of the defects in the LR image 406. As described above at least with reference to process P505, the defects on the images may be different, that is, the LR image 406 may be missing some of the defects indicated in the HR image 405, or may include some false defects, e.g., defects that are not indicated in the HR image 405. Accordingly, the defect maps of the images may also be different. For example, the second defect map 403 may not indicate all the defects indicated in the first defect map 402 or may include some false defects, e.g., defects that are not indicated in the first defect map 402. In the example of FIG. 4, the second defect map 403 does not include those defects represented using markers such as a triangle or circle/oval in the first defect map 402.

Further, the defect map generation component 425 analyzes the defect maps 402 and 403 to identify defects satisfying a specified criterion and generates a processed defect map for each of the images. For example, the defect map generation component 425 identifies defects that are common between the two defect maps 402 and 402 and generates processed defect maps, such as a first processed defect map 412 corresponding to the HR image 405 and a second processed defect map 413 having the common defects.

In some embodiments, the images 405 and 406 may not be aligned with each other for various reasons. For example, the images 405 and 406 may not be aligned due to noise or different signature of image distortion between the images 405 and 406. The defect maps 412 and 413 indicate the non-alignment between the two images 405 and 406. For example, a reference location with respect to the first image 405 (e.g., bottom left corner of the image 405) may be considered as an origin 420 of the coordinate system associated with the images. As shown in FIG. 4, the second processed defect map 413 is shifted from the origin 420 by a specified value (e.g., which is due to noise, distortion, or other factors). Accordingly, the two images 405 and 406 may have to be aligned (e.g., before they can be used in any application, such as training data for a machine learning (ML) model to generate a HR image from a LR image).

At process P520, an image alignment component 435 aligns the set of images 405 and 406 with each other using the processed defect maps 412 and 413 to generate an aligned set of images 405 and 466. In aligning the images, a defect map alignment component 430 shifts the second processed defect map 413 (e.g., towards the origin 420) so that the coordinates of the defects in the second processed defect map 413 aligns with that of the defects in the first processed defect map 412 to generate an aligned defect map 426. The direction and amount of shift associated with the aligned defect map 426, which is referred to as the “offset value,” may then be used by the image alignment component 435 in aligning the set of images 405 and 406. For example, the image alignment component 435 shifts the LR image 406 by the offset value to generate an aligned image 466 that is aligned with the HR image 405. Thus, the image alignment component 435 generates the aligned set of images 405 and 466.

At process P525, optionally, an image cropping component 440 may crop a specified portion of the aligned set of images 405 and 466 to obtain an aligned set of images 475 and 476 having only the specific portion (e.g., the defect region) of the images 405 and 466.

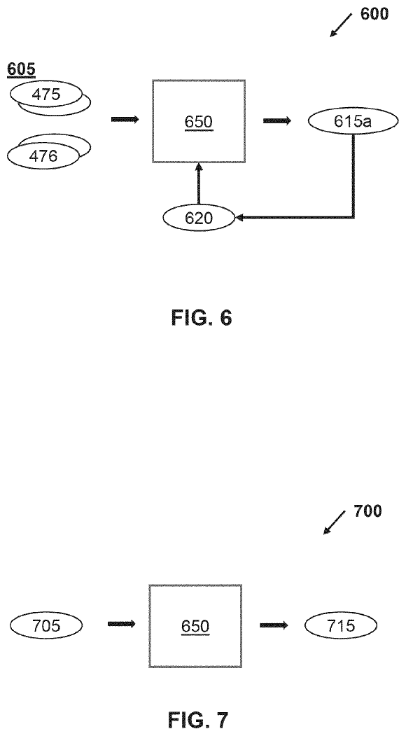

The aligned set of images 405 and 466 may be used for various purposes. For example, the aligned set of images 405 and 406 may be used as training data for training a ML model to predict a HR image of a defect region on the substrate based on a LR image of the defect region on the substrate, as described at least with reference to FIGS. 6 and 4 below.

FIG. 6 is a block diagram of a system 600 for training an image generator 650 to generate a high-resolution image of a defect on a substrate based on a low-resolution image of the defect, consistent with various embodiments. In some embodiments, the image generator 650 may be a prediction model, which may be implemented as a ML model (e.g., a neural network), a statistical model, an analytics model, a rule-based model, or any other empirical model.

Multiple sets of aligned images 605, such as the set of aligned images 475 and 476, are input to the image generator 650. In some embodiments, each set of aligned images includes a first image of a defect region of a substrate obtained in a first image capture condition (e.g., the HR image 475) and a second image of a defect region obtained in a second image capture condition (e.g., the LR image 476) that are aligned with each other (e.g., as described at least with reference to FIG. 5 above). In some embodiments, the HR image 475 acts as a reference image or ground truth image for training the image generator 650 to predict a HR image based on the LR image.

The image generator 650 generates an HR image corresponding to a target image. For example, the image generator 650 generates a HR image 615a of the defect region corresponding to the defect region in the LR image 476. The image generator 650 computes an image reconstruction loss 620, which is determined as a difference between the predicted HR image 615a and a reference image such as the HR image 475. The configuration of the image generator 650 may be updated to reduce the image reconstruction loss 620. For example, updating the image generator 650 includes updating the configurations (e.g., weights, biases, or other parameters) of a neural network based on the image reconstruction loss 620. For example, connection weights may be adjusted to reconcile differences between the neural network's prediction (e.g., predicted HR image 615a) and the reference feedback (reference image 475). In a further use case, one or more neurons (or nodes) of the neural network may require that their respective errors are sent backward through the neural network to them to facilitate the update process (e.g., backpropagation of error). Updates to the connection weights may, for example, be reflective of the magnitude of error (e.g., loss functions) propagated backward after a forward pass has been completed. In this way, for example, the image generator 650 may be trained to generate better predictions (e.g., mask images).

In some embodiments, training the image generator 650 is an iterative process in which each iteration includes generating a predicted image (e.g., predicted HR image 615a), computing a loss function (e.g., image reconstruction loss 620), determining whether the loss function is minimized, updating a configuration of the image generator 650 to reduce the loss function. The iterations may be performed until a specified condition is satisfied (e.g., a predetermined number of iterations, until the loss function is minimized, or another condition). After the training is completed, the image generator 650 is considered to be trained, which may be used to generate or predict a HR image of a specified defect region at a specified location for any given substrate based on the LR image of the specified defect region (a) in the same location on the substrate (e.g., the same die) or (b) in a different location on the substrate (e.g., a different die).

FIG. 7 is a block diagram of a system 700 for predicting a high-resolution image of a defect on a substrate based on a low-resolution image of the defect, consistent with various embodiments. An image 705 of a defect region on a substrate is input to a trained image generator 650. The image 705 may be a low-resolution image (e.g., image resolution below a specified threshold) of the defect region on a substrate, which may be obtained using a SEM. The image generator 650 is executed to generate a high-resolution image 715 (e.g., image resolution above the specified threshold) of the defect region on the substrate.

The predicted HR image may be used for various purposes. For example, after inspecting the defects in the predicted HR image, the patterning process or a lithographic apparatus may be optimized or adjusted (e.g., one or more parameters of a patterning process or a lithographic apparatus) to minimize the defects in patterning a target layout on the substrate. The optimized patterning process is then performed to print patterns corresponding to the target layout on the substrate.

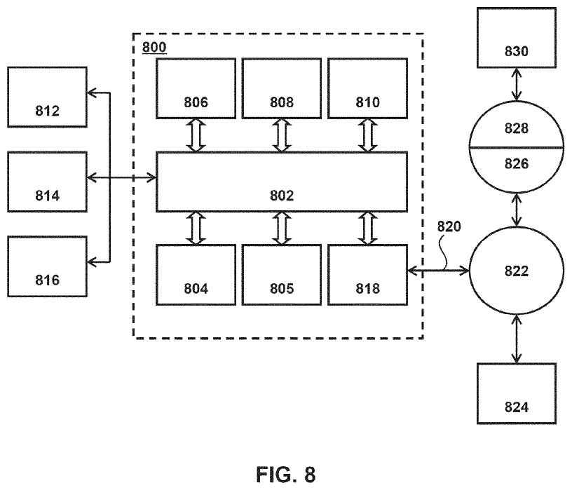

FIG. 8 is a block diagram that illustrates a computer system 800 which can assist in implementing in various methods and systems disclosed herein. The computer system 800 may be used to implement any of the entities, components, modules, or services depicted in the examples of the figures (and any other entities, components, modules, or services described in this specification). The computer system 800 may be programmed to execute computer program instructions to perform functions, methods, flows, or services (e.g., of any of the entities, components, or modules) described herein. The computer system 800 may be programmed to execute computer program instructions by at least one of software, hardware, or firmware.

Computer system 800 includes a bus 802 or other communication mechanism for communicating information, and a processor 804 (or multiple processors 804 and 805) coupled with bus 802 for processing information. Computer system 800 also includes a main memory 806, such as a random access memory (RAM) or other dynamic storage device, coupled to bus 802 for storing information and instructions to be executed by processor 804. Main memory 806 also may be used for storing temporary variables or other intermediate information during execution of instructions to be executed by processor 804. Computer system 800 further includes a read only memory (ROM) 808 or other static storage device coupled to bus 802 for storing static information and instructions for processor 804. A storage device 810, such as a magnetic disk or optical disk, is provided and coupled to bus 802 for storing information and instructions.

Computer system 800 may be coupled via bus 802 to a display 812, such as a cathode ray tube (CRT) or flat panel or touch panel display for displaying information to a computer user. An input device 814, including alphanumeric and other keys, is coupled to bus 802 for communicating information and command selections to processor 804. Another type of user input device is cursor control 816, such as a mouse, a trackball, or cursor direction keys for communicating direction information and command selections to processor 804 and for controlling cursor movement on display 812. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 800 in response to processor 804 executing one or more sequences of one or more instructions contained in main memory 806. Such instructions may be read into main memory 806 from another computer-readable medium, such as storage device 810. Execution of the sequences of instructions contained in main memory 806 causes processor 804 to perform the process steps described herein. One or more processors in a multi-processing arrangement may also be employed to execute the sequences of instructions contained in main memory 806. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 804 for execution. Such a medium may take many forms, including but not limited to, non-volatile media, volatile media, and transmission media. Non-volatile media include, for example, optical or magnetic disks, such as storage device 810. Volatile media include dynamic memory, such as main memory 806. Transmission media include coaxial cables, copper wire and fiber optics, including the wires that comprise bus 802. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 804 for execution. For example, the instructions may initially be borne on a magnetic disk of a remote computer. The remote computer can load the instructions into its dynamic memory and send the instructions over a telephone line using a modem. A modem local to computer system 800 can receive the data on the telephone line and use an infrared transmitter to convert the data to an infrared signal. An infrared detector coupled to bus 802 can receive the data carried in the infrared signal and place the data on bus 802. Bus 802 carries the data to main memory 806, from which processor 804 retrieves and executes the instructions. The instructions received by main memory 806 may optionally be stored on storage device 810 either before or after execution by processor 804.

Computer system 800 also preferably includes a communication interface 818 coupled to bus 802. Communication interface 818 provides a two-way data communication coupling to a network link 820 that is connected to a local network 822. For example, communication interface 818 may be an integrated services digital network (ISDN) card or a modem to provide a data communication connection to a corresponding type of telephone line. As another example, communication interface 818 may be a local area network (LAN) card to provide a data communication connection to a compatible LAN. Wireless links may also be implemented. In any such implementation, communication interface 818 sends and receives electrical, electromagnetic, or optical signals that carry digital data streams representing various types of information.

Network link 820 typically provides data communication through one or more networks to other data devices. For example, network link 820 may provide a connection through local network 822 to a host computer 824 or to data equipment operated by an Internet Service Provider (ISP) 826. ISP 826 in turn provides data communication services through the worldwide packet data communication network, now commonly referred to as the “Internet” 828. Local network 822 and Internet 828 both use electrical, electromagnetic, or optical signals that carry digital data streams. The signals through the various networks and the signals on network link 820 and through communication interface 818, which carry the digital data to and from computer system 800, are exemplary forms of carrier waves transporting the information.

Computer system 800 can send messages and receive data, including program code, through the network(s), network link 820, and communication interface 818. In the Internet example, a server 830 might transmit a requested code for an application program through Internet 828, ISP 826, local network 822 and communication interface 818. One such downloaded application may provide for the illumination optimization of the embodiment, for example. The received code may be executed by processor 804 as it is received, or stored in storage device 810, or other non-volatile storage for later execution. In this manner, computer system 800 may obtain application code in the form of a carrier wave.

Embodiments of the present disclosure can be further described by the following clauses.
1. A non-transitory computer-readable medium having instructions that, when executed by a computer, cause the computer to execute a method for image alignment, the method comprising:
   accessing a set of images of a substrate, wherein the set of images correspond to different image capture conditions;
   obtaining locations of multiple defects on the set of images;
   determining a defect map indicating relative locations of at least some of the defects; and
   aligning the set of images with each other using the defect map to generate an aligned set of images.
2. The computer-readable medium of clause 1, wherein aligning the set of images includes:
   obtaining an offset value for alignment; and
   shifting a second image of the set of images by the offset value to align with a first image of the set of images.
3. The computer-readable medium of clause 2, wherein the first image corresponds to a first image capture condition, and the second image corresponds to a second image capture condition.
4. The computer-readable medium of clause 2, wherein the first image is of a greater resolution than the second image.
5. The computer-readable medium of clause 2, wherein obtaining the offset value includes:
   generating a first defect map indicative of locations of a set of the defects on the first image;
   generating a second defect map indicative of locations of the set of the defects on the second image;
   shifting the second defect map until the locations of the set of the defects on the second defect map are in alignment with the locations of the set of the defects on the first defect map; and obtaining the offset value based on the shifting.
6. The computer-readable medium of clause 5, wherein the set of the defects includes defects that are common between the defects on the first image and the second image.
7. The computer-readable medium of clause 2 further comprising:
   cropping defect location area from each of the first image and the second image.
8. The computer-readable medium of clause 1, wherein obtaining the locations of the defects includes:
   obtaining (a) first defect data that is indicative of locations of a first set of the defects on a first image of the set of images, and (b) second defect data that is indicative of locations of a second set of the defects in a second image of the set of images.
9. The computer-readable medium of clause 1, wherein the defect map is an image including multiple markers placed at the locations of the defects, wherein in each marker is representative of a defect of the defects.
10. The computer-readable medium of clause 1 further comprising:
   obtaining multiple aligned sets of images, wherein each aligned set of images includes a first image that is aligned with a second image, wherein the second image is of a lower resolution compared to that of the first image; and
   training a machine learning model to generate a predicted image of the substrate based on the aligned sets of images, wherein the predicted image is of a greater resolution than the second image.
11. The computer-readable medium of clause 10 further comprising:
   inputting a first specified image of a specified substrate to the machine learning model, the first image including one or more defects on the specified substrate; and
   executing the machine learning model to generate a second specified image based on the first specified image, wherein the second specified image is of a greater resolution than the first specified image, and wherein the second specified image includes a group of defects on the specified substrate.
12. The computer-readable medium of clause 11 further comprising:
   adjusting one or more parameters of a patterning process or a lithographic apparatus based on the second specified image to minimize the group of defects in patterning a target layout on the substrate.
13. The computer-readable medium of clause 12 further comprising:
   performing the patterning process via the lithographic apparatus to print patterns corresponding to the target layout on the substrate.
14. A non-transitory computer-readable medium having instructions that, when executed by a computer, cause the computer to execute a method for training a machine learning model to generate an image indicative of defects on a substrate, the method comprising:
   obtaining a set of images of the substrate, wherein the set of images correspond to different image capture conditions;
   generating a defect map associated with set of images;
   aligning the set of images with each other based on the defect map to generate an aligned set of images; and
   training, based on multiple aligned sets of images, a neural network to generate a predicted image of the substrate, wherein the predicted image includes a group of defects on the substrate.
15. The computer-readable medium of clause 14, wherein aligning the set of images includes: obtaining an offset value for alignment; and
   shifting a second image of the set of images by the offset value to align with a first image of the set of images.
16. The computer-readable medium of clause 15, wherein the first image corresponds to a first image capture condition, and the second image corresponds to a second image capture condition.
17. The computer-readable medium of clause 15, wherein the first image is of a greater resolution than the second image.
18. The computer-readable medium of clause 15, wherein obtaining the offset value includes:
   generating a first defect map indicative of locations of a set of the defects on the first image;
   generating a second defect map indicative of locations of the set of the defects on the second image;
   shifting the second defect map until the locations of the set of the defects on the second defect map are in alignment with the locations of the set of the defects on the first defect map; and obtaining the offset value based on the shifting.
19. The computer-readable medium of clause 18, wherein the set of the defects includes defects that are common between the defects on the first image and the second image.
20. The computer-readable medium of clause 15 further comprising:
   cropping defect location area from each of the first image and the second image.
21. The computer-readable medium of clause 14, wherein generating the defect map includes:
   obtaining (a) first defect data that is indicative of locations of a first set of the defects on a first image of the set of images, and (b) second defect data that is indicative of locations of a second set of the defects in a second image of the set of images.
22. The computer-readable medium of clause 15, wherein the defect map is an image including multiple markers placed at locations of the defects, wherein in each marker is representative of a defect of the defects.
23. The computer-readable medium of clause 14 further comprising:
   inputting a first specified image of a specified substrate to the machine learning model, the first image including one or more defects on the specified substrate; and
   executing the machine learning model to generate a second specified image based on the first specified image, wherein the second specified image is of a greater resolution than the first specified image, and wherein the second specified image includes a group of defects on the specified substrate.
24. A method for image alignment, the method comprising:
   accessing a set of images of a substrate, wherein the set of images correspond to different image capture conditions;
   obtaining locations of multiple defects on the set of images;
   determining a defect map indicating relative locations of at least some of the defects; and
   aligning the set of images with each other using the defect map to generate an aligned set of images.
25. An apparatus for image alignment, the apparatus comprising:
   a memory storing a set of instructions; and
   a processor configured to execute the set of instructions to cause the apparatus to perform a method of:
      accessing a set of images of a substrate, wherein the set of images correspond to different image capture conditions;
      obtaining locations of multiple defects on the set of images;
      determining a defect map indicating relative locations of at least some of the defects; and
         aligning the set of images with each other using the defect map to generate an aligned set of images.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

The descriptions herein are intended to be illustrative, not limiting. Thus, it will be apparent to one skilled in the art that modifications may be made as described without departing from the scope of the claims set out below.

1. A non-transitory computer-readable medium having stored instructions that, when executed by a computer system, are configured to cause the computer system to at least:
access a set of images of a substrate, wherein the set of images correspond to different image capture conditions;
obtain locations of multiple defects on the set of images;
determine a defect map indicating relative locations of at least some of the defects; and
align the set of images with each other using the defect map to generate an aligned set of images.

2. The computer-readable medium of claim 1, wherein the set of images have different resolutions.

3. The computer-readable medium of claim 1, wherein the instructions configured to cause the computer system to align the set of images are further configured to cause the computer system to:
generate a first defect map indicative of locations of a set of the defects on a first image of the set of images;
generate generating a second defect map indicative of locations of the set of the defects on a second image of the set of images;
shift the second defect map until the locations of the set of the defects on the second defect map are in alignment with the locations of the set of the defects on the first defect map;
obtaining an the offset value based on the shift of the second defect map; and
shift the second image by the offset value to align with the first image.

4. The computer-readable medium of claim 3, wherein the set of the defects includes defects that are common between the defects on the first image and the second image.

5. The computer-readable medium of claim 1, wherein the instructions are further configured to cause the computer system to crop defect location area from each of the set of images.

6. The computer-readable medium of claim 1, wherein the defect map comprises multiple markers placed at the locations of the defects, wherein each marker is representative of a defect of the defects.

7. The computer-readable medium of claim 1, wherein the instructions are further configured to cause the computer system to:
obtain multiple aligned sets of images, wherein each aligned set of images includes a first image that is aligned with a second image, wherein the second image is of a lower resolution compared to that of the first image; and
train a machine learning model to generate a predicted image of the substrate based on the aligned sets of images, wherein the predicted image is of a greater resolution than the second image.

8. The computer-readable medium of claim 7, wherein the instructions are further configured to cause the computer system to:
input a first specified image of a specified substrate to the machine learning model, the first image including one or more defects on the specified substrate; and
execute the machine learning model to generate a second specified image based on the first specified image, wherein the second specified image is of a greater resolution than the first specified image, and wherein the second specified image includes a group of defects on the specified substrate.

9. The computer-readable medium of claim 8, wherein the instructions are further configured to cause the computer system to adjust one or more parameters of a patterning process or a lithographic apparatus based on the second specified image to minimize the group of defects in patterning a target layout on the substrate.

10. A non-transitory computer-readable medium having stored instructions that, when executed by a computer system, are configured to cause the computer system to at least:
obtain a set of images of a substrate, wherein the set of images correspond to different image capture conditions;
generate a defect map associated with set of images;
align aligning the set of images with each other based on the defect map to generate an aligned set of images; and
train, based on multiple aligned sets of images, a neural network to generate a predicted image of the substrate, wherein the predicted image includes a group of defects on the substrate.

11. The computer-readable medium of claim 10, wherein the instructions configured to cause the computer system to align the set of images are further configured to cause the computer system to:
generate a first defect map indicative of locations of a set of the defects on a first image of the set of images;
generate a second defect map indicative of locations of the set of the defects on a second image of the set of images;
shift the second defect map until the locations of the set of the defects on the second defect map are in alignment with the locations of the set of the defects on the first defect map;
obtaining an offset value based on the shift of the second defect map; and
shift the second image by the offset value to align with the first image.

12. The computer-readable medium of claim 10, wherein the set of the defects includes defects that are common between the defects on the first image and the second image.

13. The computer-readable medium of claim 11, wherein the instructions are further configured to cause the computer system to crop defect location area from each of the first image and the second image.

14. The computer-readable medium of claim 12, wherein the defect map is an image including multiple markers placed at locations of the defects, wherein each marker is representative of a defect of the defects.

15. The computer-readable medium of claim 11, wherein the instructions are further configured to cause the computer system to:
input a first specified image of a specified substrate to the machine learning model, the first image including one or more defects on the specified substrate; and
execute the machine learning model to generate a second specified image based on the first specified image, wherein the second specified image is of a greater resolution than the first specified image, and wherein the second specified image includes a group of defects on the specified substrate.

16. The computer-readable medium of claim 10, wherein the instructions configured to cause the computer system to generate the defect map are further configured to cause the computer system to obtain (a) first defect data that is indicative of locations of a first set of the defects on a first image of the set of images, and (b) second defect data that is indicative of locations of a second set of the defects in a second image of the set of images.

17. The computer-readable medium of claim 10, wherein the instructions are further configured to cause the computer system to adjust one or more parameters of a patterning process or a lithographic apparatus based on the trained neural network to minimize the group of defects in patterning a target layout on a substrate.

18. A method comprising:
accessing a set of images of a substrate, wherein the set of images correspond to different image capture conditions;
obtaining locations of multiple defects on the set of images;
determining a defect map indicating relative locations of at least some of the defects; and
aligning, by a hardware computer system, the set of images with each other using the defect map to generate an aligned set of images.

19. The method of claim 18, further comprising:
obtaining multiple aligned sets of images, wherein each aligned set of images includes a first image that is aligned with a second image, wherein the second image is of a lower resolution compared to that of the first image; and
training a machine learning model to generate a predicted image of the substrate based on the aligned sets of images, wherein the predicted image is of a greater resolution than the second image.

20. The method of claim 18, further comprising adjusting one or more parameters of a patterning process or a lithographic apparatus based on the second specified image to minimize the group of defects in patterning a target layout on the substrate.
